(19) United States
(12) Patent Application Publication
(10) Pub. No.: US 2026/0157171 A1
(43) Pub. Date: Jun. 4, 2026

(54) THERMAL BAR STRUCTURE IN AN EMBEDDED TRACE SUBSTRATE

(71) Applicant: TEXAS INSTRUMENTS INCORPORATED, DALLAS, TX (US)

(72) Inventors: CHUN PING LO, ALLEN, TX (US); ANINDYA PODDAR, SUNNYVALE, CA (US); VIVEK KISHORECHAND ARORA, SAN JOSE, CA (US)

(21) Appl. No.: 18/963,924

(22) Filed: Nov. 29, 2024

(51) Int. Cl. H01L 23/367; H01L 21/768; H01L 23/522; H01L 23/532

(52) U.S. Cl. CPC H10W 40/22; H10W 20/056; H10W 20/42; H10W 20/4421

(57) ABSTRACT

Integrated circuit devices and methods for fabricating the same are provided. A method includes forming a first metal trace layer having a first trace pattern of a conductive material on a first carrier surface of a carrier. The method also includes forming a first insulator layer on the first metal trace layer, the first insulator layer including a first signal via having a first via width and a first thermal bar having a first thermal bar width. The method further includes forming a second metal trace layer. The method yet further includes forming a second insulator layer on the second metal trace layer, the second insulator layer including a second signal via having a second via width and a second thermal bar having a second thermal bar width. The method includes forming a third metal trace layer. The method includes detaching the first metal trace layer from the carrier.

### TECHNICAL FIELD

This description relates to fabricating an embedded trace substrate having a signal via and a thermal bar.

### BACKGROUND

Packaged microelectronic assemblies, such as memory chips, microprocessor chips, and power management chips, typically include a die mounted to a substrate encased in a plastic protective covering. For high performance applications, demand for highly integrated packages has increased. When the high-density I/O signals operate for the highest performance, heat generation increases on the die. The high heat generation without effective heat dissipation has adverse effects on reliability and electrical performance of electronic products.

### SUMMARY

In one example, a method of forming a package substrate for an integrated circuit (IC) device is provided. The method includes forming a first metal trace layer having a first trace pattern of a conductive material on a first carrier surface of a carrier. The method also includes forming a first insulator layer on the first metal trace layer. The first insulator layer includes a first signal via having a first via width and a first thermal bar having a first thermal bar width. The first thermal bar width is at least twice the first via width in a lateral direction. The method further includes forming a second metal trace layer including a second trace pattern of the conductive material. The conductive material of the second trace pattern contacts the first signal via and the first thermal bar. The method yet further includes forming a second insulator layer on the second metal trace layer. The second insulator layer includes a second signal via having a second via width and a second thermal bar having a second thermal bar width, wherein the second thermal bar width is at least twice the second via width. The method includes forming a third metal trace layer including a third trace pattern of the conductive material. The conductive material of the third trace pattern contacts the second signal via and the second thermal bar. The method also includes detaching the first metal trace layer from the carrier. The package substrate extends from a first outer surface of the first metal trace layer to a second outer surface at the third metal trace layer.

In a second example, a method of forming an integrated circuit (IC) device is provided. The method includes forming a first metal trace layer of a conductive material on a first carrier surface of a carrier. The method also includes depositing an insulator material on the first metal trace layer. The method further includes drilling a first single via opening to form a first via opening in the insulator material and a first series of overlapping via openings to form a first thermal bar opening in the insulator material. The first thermal bar opening is separated from the single via opening in a lateral direction. The method yet further includes depositing the conductive material in the first via opening to form a first signal via and the first thermal bar. The method includes forming a second metal trace layer including a second trace pattern of the conductive material. The conductive material of the second trace pattern contacts the first signal via and the first thermal bar. The method also includes depositing the insulator material on the second metal trace layer. The method further includes drilling a second single via opening to form a second via opening in the insulator material and a second series of overlapping via openings to form a second thermal bar opening in the insulator material. The second thermal bar opening is separated from the single via opening in a lateral direction. The method yet further includes depositing the conductive material in the second via opening to form a second signal via and the second thermal bar. The method includes forming a third metal trace layer including a third trace pattern of the conductive material. The conductive material of the third trace pattern contacts the second signal via and the second thermal bar. The method also includes detaching the first metal trace layer from the carrier forming a package substrate that extends from a first outer surface of the first metal trace layer to a second outer surface at the third metal trace layer. The method further includes applying a first solder resist layer to the first outer surface. The first solder resist layer has a first mounting opening in the first outer surface. The method yet further includes applying a second solder resist layer to the second outer surface. The second solder resist layer has a second mounting opening separated from the first mounting opening by the first signal via and the second signal via in a longitudinal direction. The method includes attaching a semiconductor die at a second contact pad at the second mounting opening.

In a third example, an integrated circuit (IC) device is provided. The IC device includes a first metal trace layer having a first trace pattern of a conductive material. The IC device also includes a first insulator layer over the first metal trace layer. The first insulator layer of an insulator material includes a first signal via of the conductive material having a first via width and a first thermal bar of the conductive material having a first thermal bar width. The IC device further includes a second metal trace layer including a second trace pattern of the conductive material. The conductive material of the second trace pattern contacts the first signal via and the first thermal bar. The IC device yet further includes a second insulator layer on the second metal trace layer. The second insulator layer of the insulator material includes a second signal via of the conductive material having a second via width and a second thermal bar of the conductive material having a second thermal bar width. The IC device includes a third metal trace layer including a third trace pattern of the conductive material. The conductive material of the third trace pattern contacts the second signal via and the second thermal bar.

### BRIEF DESCRIPTION OF THE DRAWINGS

FIG. 1 illustrates an example of a side view of a package substrate for an integrated circuit (IC) device.

FIGS. 2A-C are a top view of a number of metal trace layers of the package substrate for the IC device.

FIGS. 3-32 illustrate example stages of a method for forming the package substrate for an IC device.

FIG. 33 illustrates a flowchart of an example method for fabricating a package substrate for an IC device.

### DETAILED DESCRIPTION

As a large amount of heat is produced during operation of the highly integrated semiconductor chip, effective thermal dissipation is important to assure the performance and the lifetime of the integrated circuit (IC) device. Conventionally, a routable lead frame (RLF) has been used to provide components that move heat away from the semiconductor chips. However, RLFs tend to be brittle and have limited safe operation area (SOA), for example, an SOA of less than 8×8 mm. Embedded trace substrates (ETS) are more robust than RLFs and more widely available, but typically do not have same thermal dissipation as an RLF.

This description relates to a thermal bar structure to increase the thermal dissipation of package substrates, such as embedded trace substrates. The package substrate utilizes an insulator material (e.g., a polymer matrix material, prepeg material, etc.) for support. Here, overlapping vias are formed in the insulator material to form rectangular cavities. The rectangular cavities are filled with a conductive material, such as copper, to form a thermal bar in the package substrate. The thermal bar draws heat from semiconductor devices affixed to the package substrate thereby improving thermal dissipation.

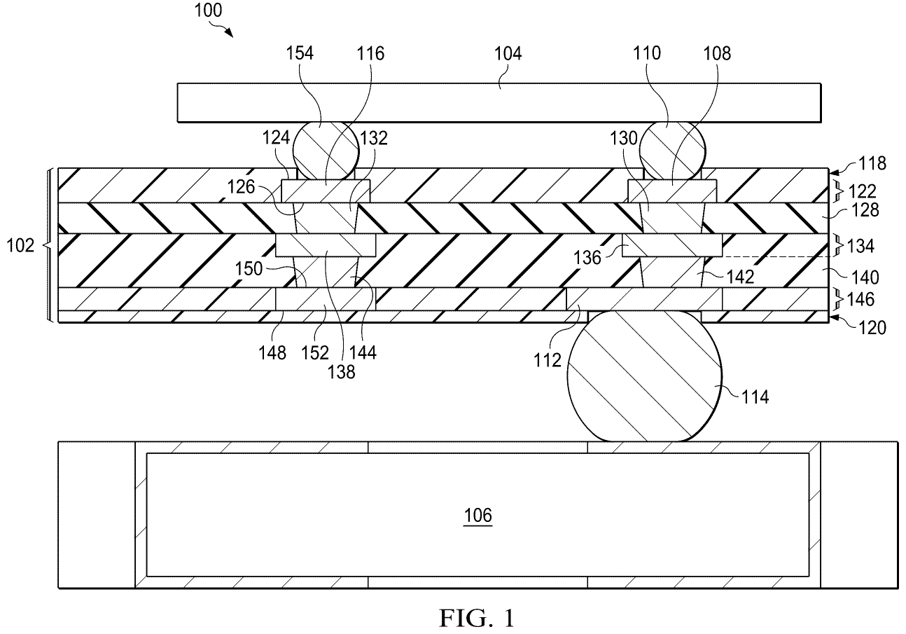

FIG. 1 illustrates an IC device 100 having a package substrate 102, a semiconductor die 104, and an electrical component 106. The package substrate 102 electrically connects the semiconductor die 104 to the electrical component 106. In particular, the semiconductor die 104 is in contact with a first contact pad 108 of the package substrate 102. For example, the semiconductor die 104 has a signal pin 110 is in contact with the first contact pad 108. The electrical component 106 is affixed to a second contact pad 112 of the package substrate 102. Accordingly, an electrical pathway is provided between the semiconductor die 104 and the electrical component 106 through the package substrate 102 from the first contact pad 108 to the second contact pad 112.

The electrical component 106 may be one or more passive electrical devices (e.g., resistors, capacitors, inductors, etc.) or active electrical devices (e.g., power supplies, transistors, light-emitting diodes, amplifiers, etc.). In some examples, the electrical component 106 is electrically connected to the second contact pad 112 through an electrical contact 114. As some examples, the electrical contact 114 may include a solder ball, a ball grid array (BGA), or a land grid array (LGA).

The package substrate 102 additionally includes a third contact pad 116. The semiconductor die 104 is affixed to the package substrate 102 at the third contact pad 116. For example, the semiconductor die 104 has a thermal pin 154 is in contact with the third contact pad 116. Accordingly, the third contact pad 116 does not provide an electrical pathway between the semiconductor die 104 and another electrical component, such as the electrical component 106. Instead, the third contact pad 116 transfers heat generated by the semiconductor die 104 away from the semiconductor die 104 through the thermal pin 154.

The package substrate 102 may include a first solder resist layer 118 and a second solder resist layer 120. The first solder resist layer 118 and the second solder resist layer 120 are protective layers that shield the interior of the package substrate 102. The first solder resist layer 118 and the second solder resist layer 120 are formed of nonconductive materials, such as polymers. The first solder resist layer 118 exposes and electrically isolates the first contact pad 108 and the third contact pad 116. The second solder resist layer 120 exposes the second contact pad 112. The first solder resist layer 118 or the second solder resist layer 120 is continuous in the lateral direction over the first thermal bar 132.

The interior of the package substrate 102 includes a first metal trace layer 122 having a first trace pattern. The first metal trace layer 122 has a first outer surface 124 opposite a first interior surface 126. The first solder resist layer 118 is applied to the first outer surface 124 of the first metal trace layer 122. A first insulator layer 128 is laminated between the first metal trace layer 122 and a second metal trace layer 134. The first trace pattern is formed of an electrically conductive material, such as copper, palladium, gold, silver, or other appropriate conductive metal or metal alloys with similar properties. The first trace pattern of the first metal trace layer 122 includes multiple bonding pads such as the first contact pad 108 and the third contact pad 116.

The first insulator layer 128 is formed of an insulator material, such as a polymer matrix material, prepeg material, silicon dioxide (SiO₂), silicon nitride (Si₃N₄), polyimide, benzocyclobutene (BCB), or other suitable materials. The first insulator layer 128 includes a first signal via 130 and a first thermal bar 132 formed of a conductive material, which may be the same or different than the conductive material of the first trace pattern of the first metal trace layer 122. The first signal via 130 and the first thermal bar 132 are separated in the lateral direction by the insulator material of the first insulator layer 128. The first signal via 130 has a first via width defined in the lateral direction. The first thermal bar 132 has a first thermal bar width defined in the lateral direction. The first thermal bar width is at least twice the first via width in a lateral direction.

The second metal trace layer 134 is separated from the first metal trace layer 122 by the first insulator layer 128. The second metal trace layer 134 includes a second trace pattern of the conductive material set in the insulator material. The second trace pattern includes a signal trace 136 and a first thermal trace 138 of the conductive material. The conductive material of the second trace pattern contacts the first signal via 130 and the first thermal bar 132. Specifically, the first signal via 130 electrically connects the first contact pad 108 to the signal trace 136. The first thermal bar 132 electrically connects the third contact pad 116 and the first thermal trace 138. The insulator material of the second metal trace layer 134 electrically isolates the signal trace 136 and the first thermal trace 138.

A second insulator layer 140 is formed of the insulator material, such as a polymer matrix material, prepeg material, silicon dioxide (SiO₂), silicon nitride (Si₃N₄), polyimide, or benzocyclobutene (BCB). The second insulator layer 140 includes a second signal via 142 and a second thermal bar 144 formed of a conductive material. The second signal via 142 and the second thermal bar 144 are separated in the lateral direction by the insulator material of the second insulator layer 140. The second signal via 142 has a second via width defined in the lateral direction. The second thermal bar 144 has a second thermal bar width defined in the lateral direction. The second thermal bar width is at least twice the second via width in a lateral direction. The first signal via 130, the first thermal bar 132, the second signal via 142, and the second thermal bar 144 have lateral edges that define the via widths in the lateral direction. The lateral edges may be orthogonal to the lateral direction or angled. The angle of lateral edges may depend on the technique of forming the first signal via 130, the first thermal bar 132, the second signal via 142, and the second thermal bar 144.

The third metal trace layer 146 has a second outer surface 148 opposite a second interior surface 150. The second solder resist layer 120 is applied to the second outer surface 148 of the third metal trace layer 146. The second insulator layer 140 contacts the second interior surface 150 of the third metal trace layer 146. The third trace pattern is formed of the electrically conductive material positioned in the insulator material. The third trace pattern of the third metal trace layer 146 includes the second contact pad 112 and a second thermal trace 152. The second contact pad 112 and the second thermal trace 152 are electrically isolated by the insulator material. The third trace pattern contacts the second signal via 142 and the second thermal bar 144. Specifically, the second signal via 142 electrically contacts the second contact pad 112. Therefore, an electrical pathway is provided from the semiconductor die 104 to the electrical component 106 that allows signals to pass between the semiconductor die 104 to the electrical component 106. The electrical pathway extends in a longitudinal direction through the package substrate 102 and includes the first contact pad 108 of the first metal trace layer 122, the first signal via 130 of the first insulator layer 128, the signal trace 136 of the second metal trace layer 134, the second signal via 142 of the second insulator layer 140, and the second contact pad 112 of the third metal trace layer 146.

A thermal bar structure provides a thermal pathway from the semiconductor die 104. Heat is dissipated through the first thermal bar 132 and the second thermal bar 144 between the third contact pad 116, the first thermal trace 138, and the second thermal trace 152 of the package substrate 102. The thermal pathway is not accessible through the second outer surface 148 because of the underlying second solder resist layer 120. The thermal bar structure includes the third contact pad 116 of the first metal trace layer 122, the first thermal bar 132 of the first insulator layer 128, the first thermal trace 138 of the second metal trace layer 134, the second thermal bar 144 of the second insulator layer 140, and the second thermal trace 152 of the third metal trace layer 146.

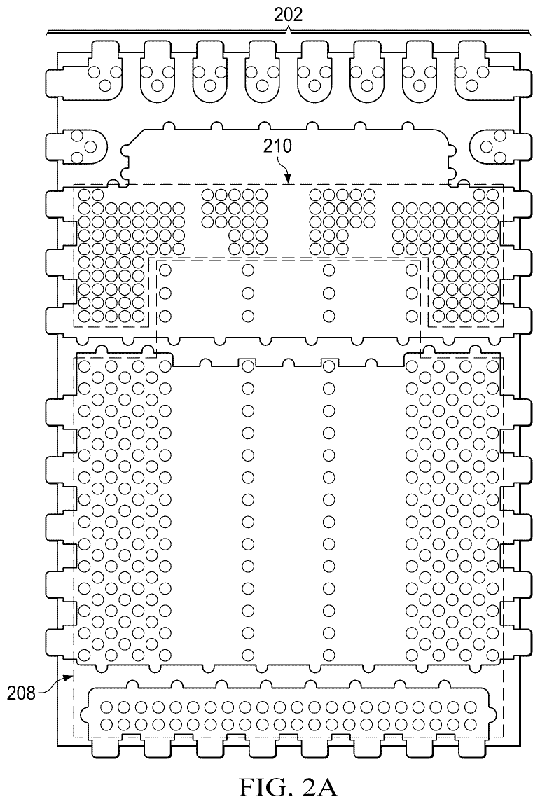

Although the package substrate 102 is shown with the three metal trace layers: the first metal trace layer 122, the second metal trace layer 134, and the third metal trace layer 146, the package substrate 102 may include more or fewer metal layers. Also, the metal trace layers 122, 134, 146 may have more signal traces and thermal traces of the conductive material, as shown with respect to FIGS. 2A-C. FIGS. 2A-C illustrate example metal trace layers of a package substrate (e.g., the package substrate 102 of FIG. 1). The metal trace layers include a first metal trace layer 202 (e.g., the first metal trace layer 122 of FIG. 1) shown in FIG. 2A, a second metal trace layer 204 (e.g., the second metal trace layer 134 of FIG. 1) shown in FIG. 2B, and a third metal trace layer 206 (e.g., the third metal trace layer 146 of FIG. 1) shown in FIG. 2C.

In FIG. 2A, the first metal trace layer 202 includes first signal traces 208 (e.g., the first contact pad 108 of FIG. 1) and first thermal traces 210 (e.g., the third contact pad 116 of FIG. 1) of the conductive material. The first signal traces 208 of the first metal trace layer 202 correspond to signal vias (e.g., the first signal via 130 of FIG. 1) in an underlying insulation layer (e.g., first insulator layer 128 of FIG. 1). The first thermal traces 210 of the first metal trace layer 202 correspond to thermal bars (e.g., the first thermal bar 132 of FIG. 1) in the underlying insulation layer. In the first metal trace layer 202, one or more of the first signal traces 208 may act as the first contact pad (e.g., the first contact pad 108 of FIG. 1). Additionally, one or more of the first thermal traces 210 may act as a third contact pad (e.g., the third contact pad 116 of FIG. 1).

In FIG. 2B, the second metal trace layer 204 includes second signal traces 212 (e.g., the signal trace 136 of FIG. 1) and second thermal traces 214 (e.g., the first thermal trace 138) of conductive material. The second signal traces 212 of the second metal trace layer 204 are in electrical communication with the first signal traces 208 of the first metal trace layer 202 through the signal vias. The second thermal traces 214 are in electrical communication with the first thermal traces 210 of the first metal trace layer 202 through the thermal bars (e.g., the second thermal bar 144 of FIG. 1). Furthermore, second signal traces 212 of the second metal trace layer 204 correspond to signal vias (e.g., the second signal via 142 of FIG. 1) in an underlying insulation layer (e.g., the second insulator layer 140 of FIG. 1). The second thermal traces 214 correspond to thermal bars in the underlying insulation layer.

In FIG. 2C, the third metal trace layer 206 includes third signal traces 216 of conductive material. The third signal traces 216 are in electrical communication with the first signal traces 208 of the first metal trace layer 202 through the signal vias and the second signal traces 212. Additionally, one or more of the third signal traces 216 may act as a second contact pad (e.g., the second contact pad 112 of FIG. 1). The third metal trace layer 206 does not include thermal traces as the thermal traces dissipate heat and do not form an electrical pathway through a package substrate. Accordingly, the signal traces and signal vias form an electrical pathway from a first outer surface (e.g., the first outer surface 124 of FIG. 1) to a second outer surface (e.g., the second outer surface 148 of FIG. 1). The thermal traces and thermal bars form a thermal pathway from the first outer surface to a penultimate layer, such as an insulation layer, of the package substrate.

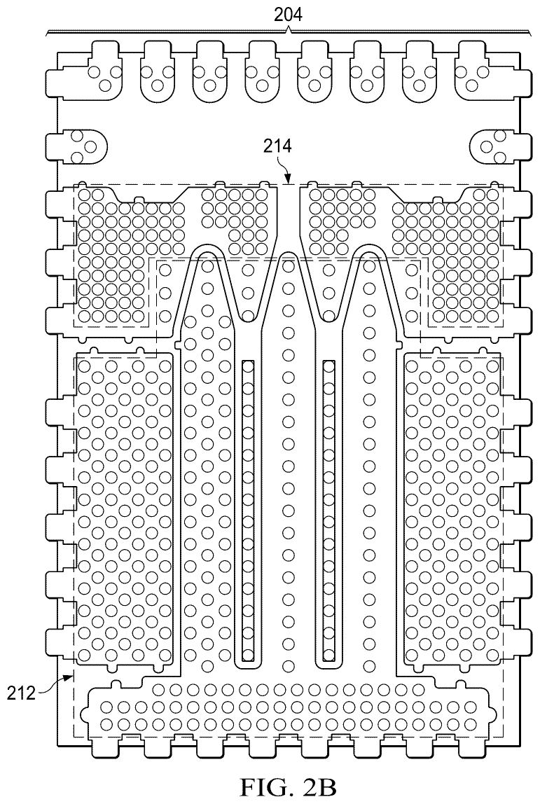

FIGS. 3-33 illustrate example stages of a method for forming the package substrate for an IC device. For purposes of simplification, FIGS. 3-33 employ the same reference numbers to denote the same structure.

FIG. 3 illustrates an example of a first stage of the process flow. A carrier 300 is provided in the first stage. The carrier 300 is a plate of a metal, an epoxy resin, a glass or other suitable materials. The carrier 300 has a first carrier surface 302 and a second carrier surface 304 opposite the first carrier surface 302 in the longitudinal direction. The carrier 300 may have a single or dual formation. In a single formation, a package substrate (e.g., the package substrate 102 of FIG. 1) is formed on one surface, such as the first carrier surface 302 or the second carrier surface 304. In a dual formation, a package substrate is fabricated on two carrier surfaces. For example, a package substrate is formed on the first carrier surface 302 and another package substrate is fabricated on the second carrier surface 304. For a clarity, the fabrication of a package substrate is described with respect to the first carrier surface 302. As shown, the same steps of the stages are performed with respect to the second carrier surface 304 of the carrier 300.

A separation film 306 is formed on the first carrier surface 302. As one example, the separation film 306 is laminated on the first carrier surface 302 with a thin release film. A seed layer 308 is formed by sputtering a conductive material over the separation film the separation film 306 306. The seed layer 308 provides an electrically conductive surface for a subsequent electroplating. The seed metal material may be based on the conductive material being used to form the metal trace layers (e.g., the first metal trace layer 122, the second metal trace layer 134, and the third metal trace layer 146 of FIG. 1, a first metal trace layer 202, a second metal trace layer 204, a third metal trace layer 206 of FIG. 2). For example, the conductive material may be copper, palladium, gold, silver, or other appropriate conductive metal or metal alloy with similar properties.

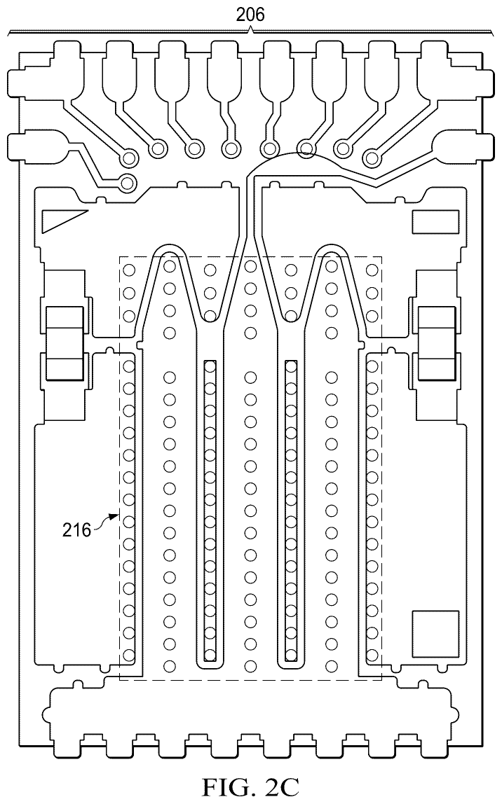

FIG. 4 illustrates an example of a second stage of the process flow. In the second stage, a passivation layer 400 is formed on the seed layer 308. The passivation layer 400 is deposited using any suitable deposition technique, such as Chemical Vapor Deposition (CVD). As some examples, the passivation layer 400 is an insulator. The passivation layer 400 is, for example, polysilicon, silicon nitride, silicon oxynitride, polyimide, etc.

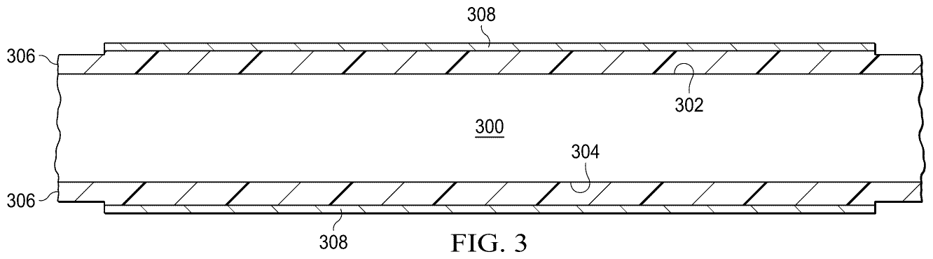

FIG. 5 illustrates an example of a third stage of the process flow. In the third stage, the passivation layer 400 is patterned to have cured portions 500 and uncured portions 502. For example, the passivation layer 400 may be a light-sensitive material used in several processes, including photolithography, photoengraving, and photoresist etching that allow underlying layers to be patterned. In one example, a photomask (not shown) is used for patterning the passivation layer 400. The photomask may be transparent over the cured portions 500 and be opaque over the uncured portions 502 of the passivation layer 400 during the exposure process. Accordingly, the passivation layer 400 is a patterned passivation layer.

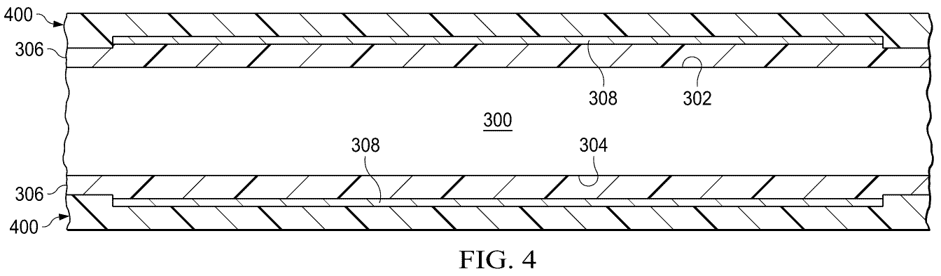

FIG. 6 illustrates an example of a fourth stage of the process flow. In the fourth stage, the uncured portions 502 are removed from the seed layer 308 leaving the cured portions 500 and voids 600 between the cured portions 500. The voids 600 exposing the seed layer 308. As one example, the uncured portions 502 are removed by applying a developer material to the passivation layer 400.

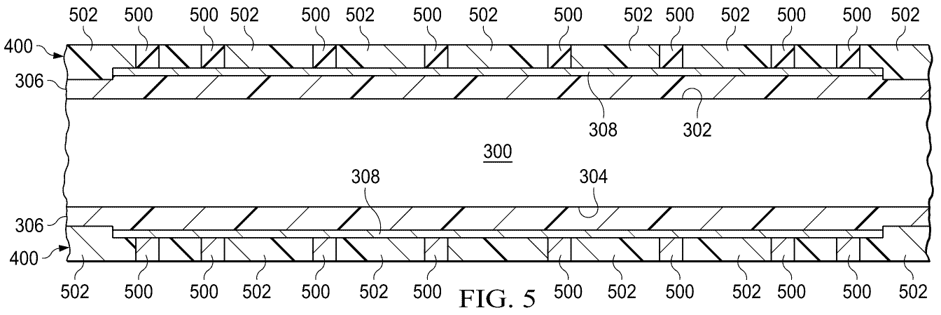

FIG. 7 illustrates an example of a fifth stage of the process flow. In the fifth stage, a conductive material 700 is deposited over the seed layer 308 in the voids 600. The conductive material 700 is the same as that of the seed layer 308. For example, the conductive material 700 is Cu. As one example, the voids 600 are filled with the conductive material 700 using a deposition or sputtering process.

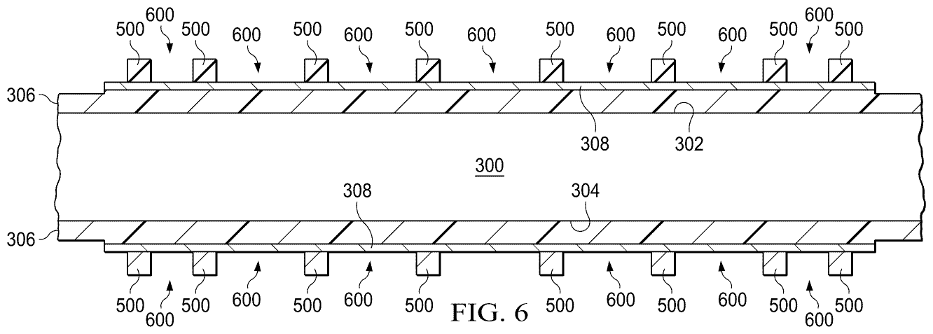

FIG. 8 illustrates an example of a sixth stage of the process flow. In the sixth stage, the cured portions 500 are removed leaving voids 802 and a first trace pattern 800 of the conductive material.

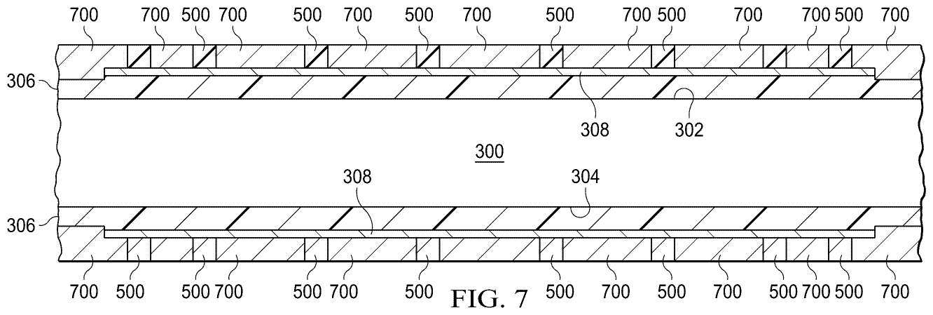

FIG. 9 illustrates an example of a seventh stage of the process flow. In the seventh stage, an insulator material 900 is deposited into the voids 802 and over the first trace pattern 800. Accordingly, the insulator material 900 forms a first metal trace layer 902 (e.g., the first metal trace layer 122 of FIG. 1) and an insulator layer (e.g., the first insulator layer 128 of FIG. 1). The insulator material 900 may be, for example, a polymer matrix material, prepeg material, silicon dioxide (SiO₂), silicon nitride (Si₃N₄), polyimide, benzocyclobutene (BCB), or other suitable materials.

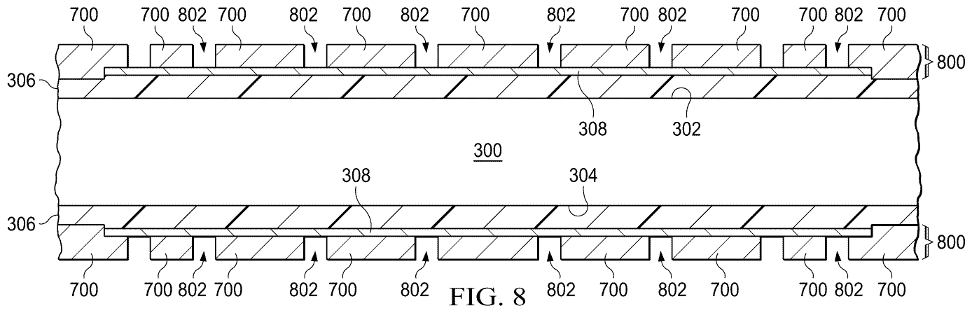

FIG. 10 illustrates an example of an eighth stage of the process flow. In the eighth stage, a seed layer 1000 is formed by sputtering the conductive material over the insulator material 900. The seed layer 1000 provides an electrically conductive surface for a subsequent electroplating operation. The conductive material may include nickel or copper.

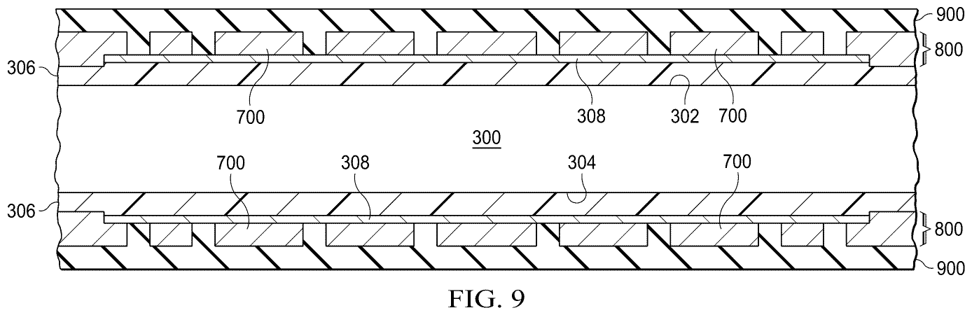

FIG. 11 illustrates an example of a ninth stage of the process flow. In the ninth stage, via openings are drilled through the insulator material 900 and the seed layer 1000. The drilling may include vaporizing using a laser drill. As one example, a focused laser beam shines into the insulator material 900 and the seed layer 1000, removing sections of the insulator material 900 and the conductive material of the seed layer 1000. In some examples, the drilling is configured to drill a single via opening 1100 in the insulator material 900 and the seed layer 1000. A first thermal bar opening 1102 is formed in the insulator material 900 and the conductive material of the seed layer 1000 by drilling overlapping via openings 1100.

The via opening 1100 has a via width 1104. As one example, the via width 1104 corresponds to the width of the drill or diameter of the laser. The thermal bar openings including the first thermal bar opening 1102 and a second thermal bar opening 1108 have a thermal bar width 1106. The thermal bar width 1106 is at least twice the via width 1104 in a lateral direction approximately orthogonal to the longitudinal direction.

The thermal bar openings are formed by drilling a series of overlapping via openings. As one example, the second thermal bar opening 1108 is formed by drilling a first via opening 1110, a second via opening 1112, and a third via opening 1114. The first via opening 1110 overlaps with the second via opening 1112 in the lateral direction such that a portion of the volume of the second via opening 1112 is shared with the volume of the first via opening 1110. Likewise, the third via opening 1114 overlaps with the second via opening 1112 in the lateral direction such that portion of the volume of the third via opening 1114 is shared with the volume of the second via opening 1112. The single via opening 1100, the first thermal bar opening 1102, and the second thermal bar opening 1108 are separated in the insulator material 900 in the lateral direction.

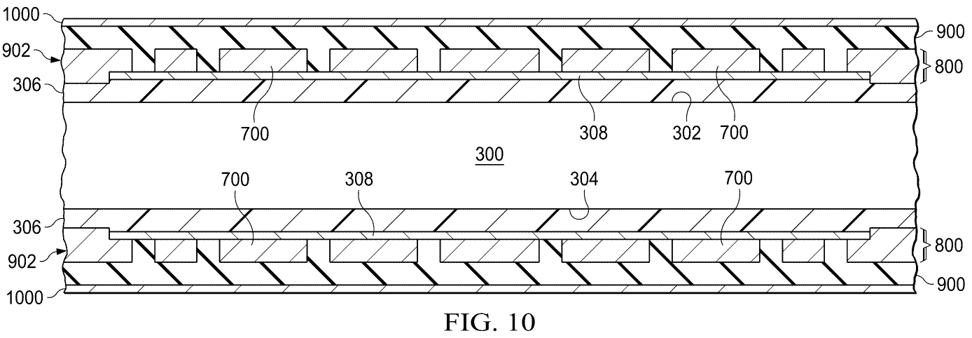

FIG. 12 illustrates an example of a tenth stage of the process flow. In the tenth stage, a passivation layer 1200 is formed on the seed layer 1000. The passivation layer 1200 is deposited using any suitable deposition technique, such as Chemical Vapor Deposition (CVD). As some examples, the passivation layer 1200 is an insulator material. The passivation layer 1200 is, for example, polysilicon, silicon nitride, silicon oxynitride, polyimide, etc.

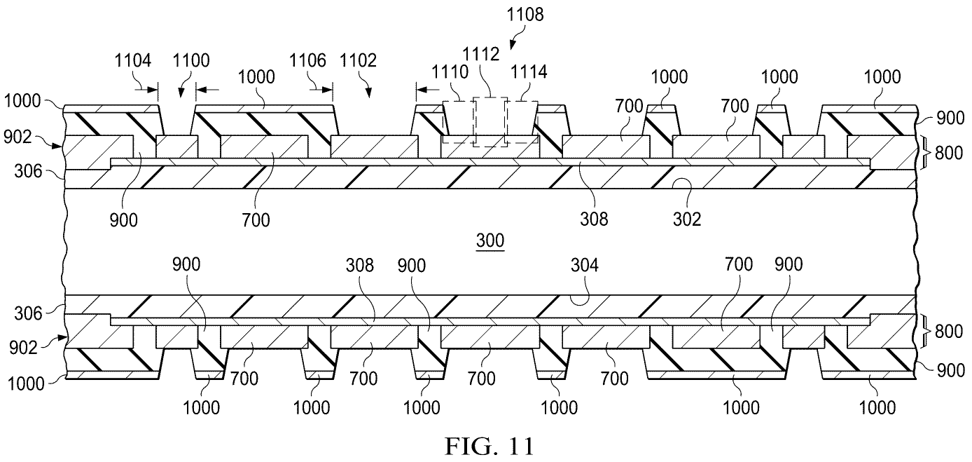

FIG. 13 illustrates an example of an eleventh stage of the process flow. In the eleventh stage, the passivation layer 1200 is patterned to have cured portions 1300 and uncured portions 1302. For example, the passivation layer 1200 may be a light-sensitive material used in several processes, including photolithography, photoengraving, and photoresist etching that allow underlying layers to be patterned. In one example, a photomask (not shown) may be used for patterning the passivation layer 1200. The photomask may be transparent over the cured portions 1300 and be opaque over the uncured portions 1302 of the passivation layer 1200 during radiation. Accordingly, the passivation layer 1200 is a patterned passivation layer.

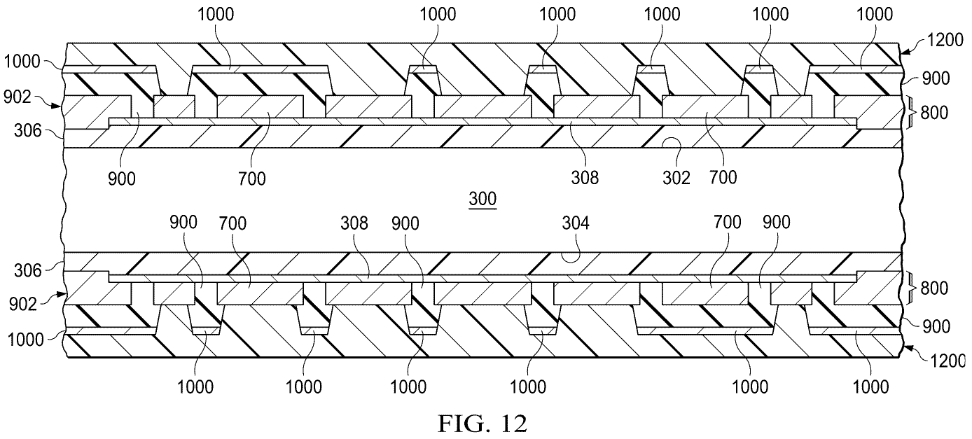

FIG. 14 illustrates an example of a twelfth stage of the process flow. In the twelfth stage, the uncured portions 1302 are removed from the seed layer 1000 leaving the cured portions 1300 and voids 1400 between the cured portions 1300. The voids 1400 exposing the seed layer 1000 and the openings including the single via opening 1100, the first thermal bar opening 1102, and the second thermal bar opening 1108.

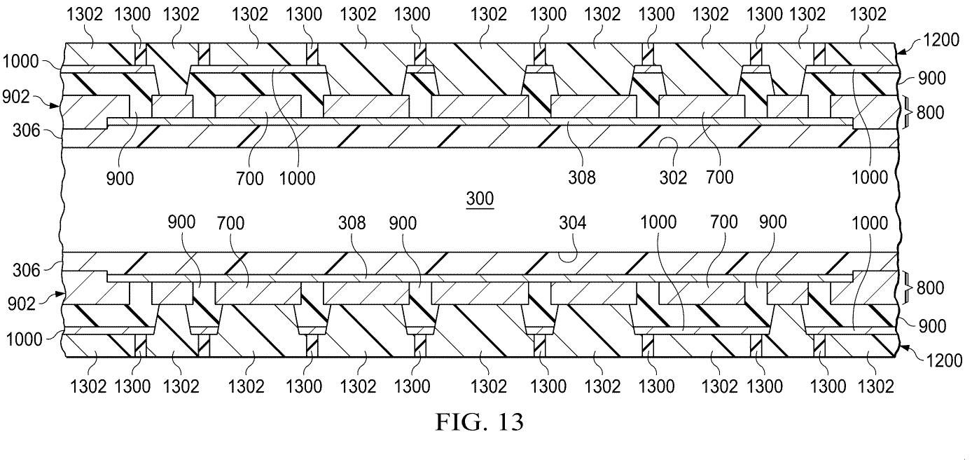

FIG. 15 illustrates an example of a thirteenth stage of the process flow. In the thirteenth stage, a conductive material 1500 is deposited over the voids 1400 exposing the seed layer 1000. For example, the conductive material 1500 in the via opening 1100 forms a signal via (e.g., the first signal via 130, the second signal via 142 of FIG. 1) having the via width 1104. The conductive material 1500 in the first thermal bar opening 1102 and a second thermal bar opening 1108 form thermal bars (e.g., the first thermal bar 132, the second thermal bar 144 of FIG. 1) having the thermal bar width 1106. In some examples, the conductive material 1500 is the same conductive material used to form the first trace pattern 800. The conductive material may be deposited using an electroplating operation.

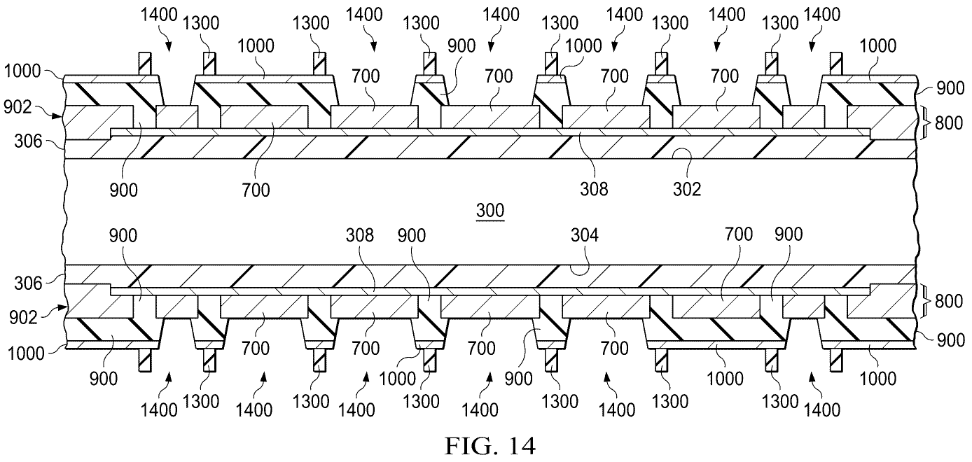

FIG. 16 illustrates an example of a fourteenth stage of the process flow. In the fourteenth stage, the cured portions 1300 are removed leaving voids 1600 and a second trace pattern 1602 of the conductive material.

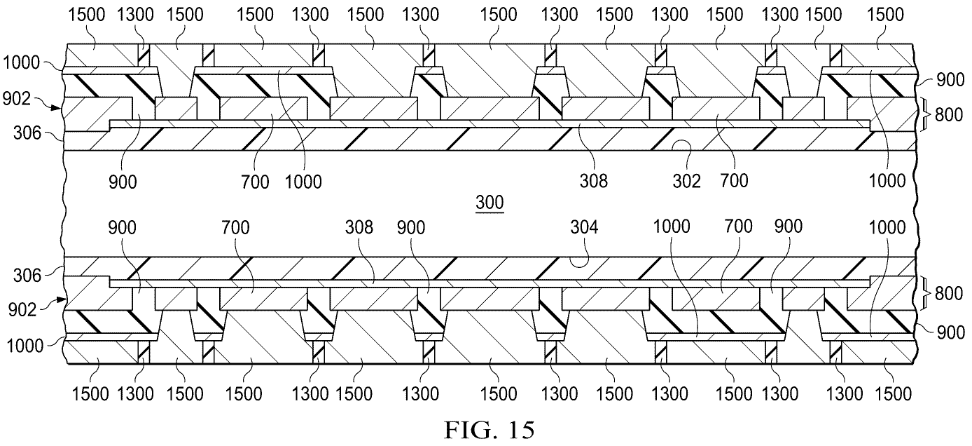

FIG. 17 illustrates an example of a fifteenth stage of the process flow. In the fifteenth stage, an insulator material 1700 is deposited into the voids 1600 and over the second trace pattern 1602. In some examples, the insulator material is the same as the insulator material 1700 of the seventh stage. The insulator material 1700 may be, for example, a polymer matrix material, prepeg material, silicon dioxide (SiO₂), silicon nitride (Si₃N₄), polyimide, benzocyclobutene (BCB), or other suitable materials. Accordingly, the insulator material 1700 forms a second metal trace layer 1702 (e.g., the second metal trace layer 134 of FIG. 1) and an insulator layer (e.g., the second insulator layer 140 of FIG. 1).

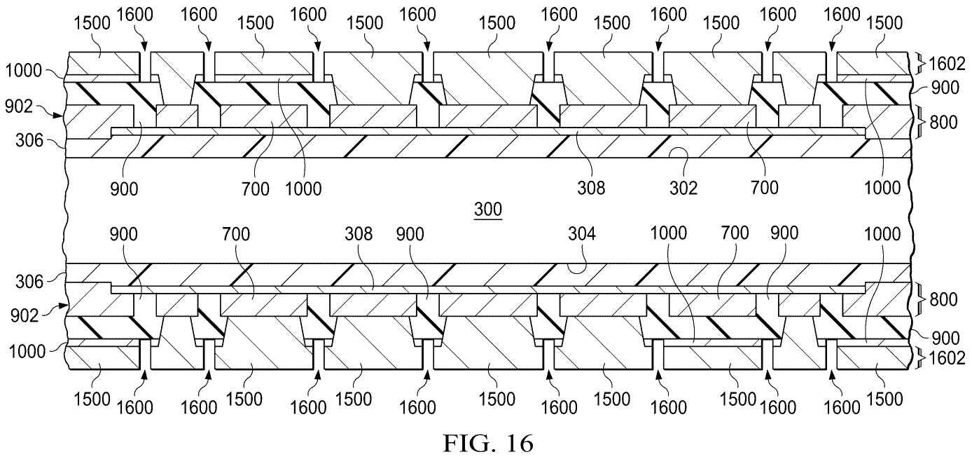

FIG. 18 illustrates an example of a sixteenth stage of the process flow. In the sixteenth stage, a seed layer 1800 is formed by sputtering the conductive material over the insulator material 1700. The seed layer 1800 provides an electrically conductive surface for a subsequent electroplating operation. The conductive material is the same as the conductive material of the seed layer 308 and the seed layer 1000.

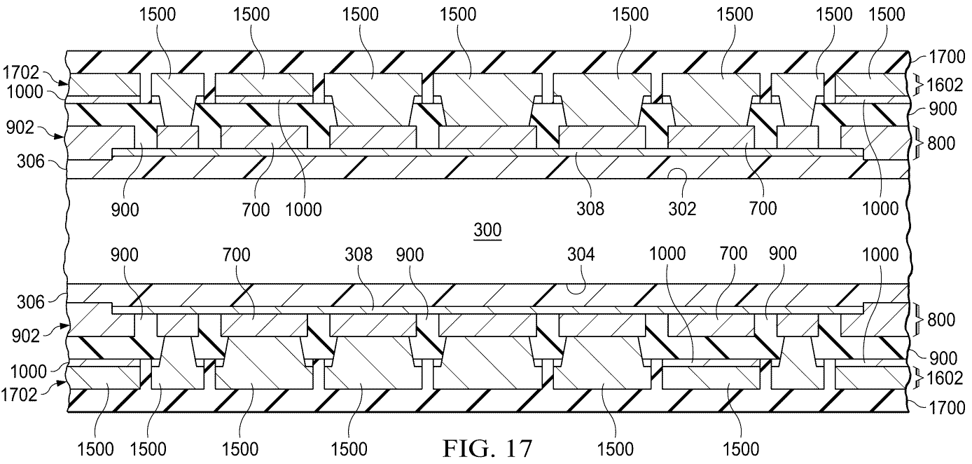

FIG. 19 illustrates an example of a seventeenth stage of the process flow. In the seventeenth stage, via opening are drilled through the insulator material 1700 and the seed layer 1800. In some examples, the drilling is configured to drill a second via opening 1900 in the insulator material 1700 and the seed layer 1800. A third thermal bar opening 1902 is formed in the insulator material 1700 and the conductive material of the seed layer 1800 by drilling a series of overlapping via openings in a similar manner as described above with respect to the ninth stage.

The second via opening 1900 has a via width 1904. The via width 1904 may be the same or different than the via width 1104. As one example, the via width 1904 corresponds to the width of the drill or diameter of the laser. The third thermal bar opening 1902 has a thermal bar width 1906. The thermal bar width 1906 may be different than the thermal bar width 1106. However, the thermal bar width 1906 is at least twice the via width 1904 in a lateral direction.

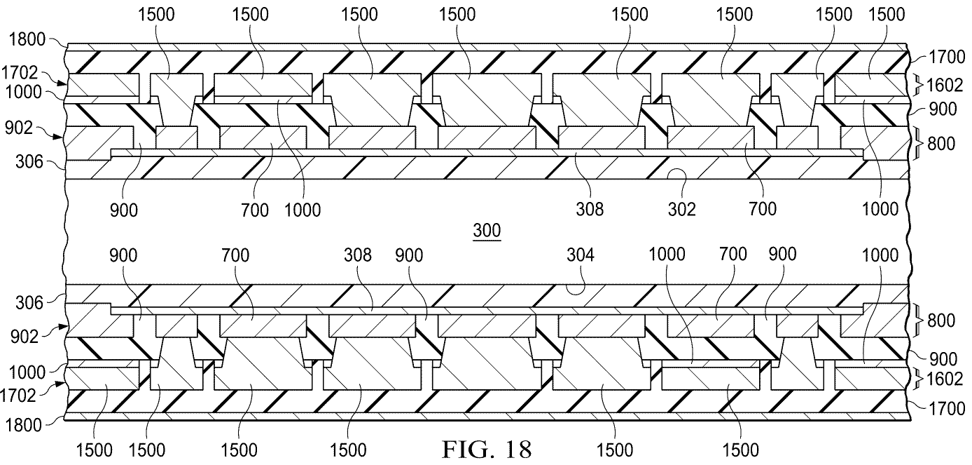

FIG. 20 illustrates an example of an eighteenth stage of the process flow. The third trace pattern is made in similar manner as described with respect to the first trace pattern 800 and the second trace pattern 1602 in the previous stages. For example, in the eighteenth stage a passivation layer 2000 is formed on the seed layer 1800.

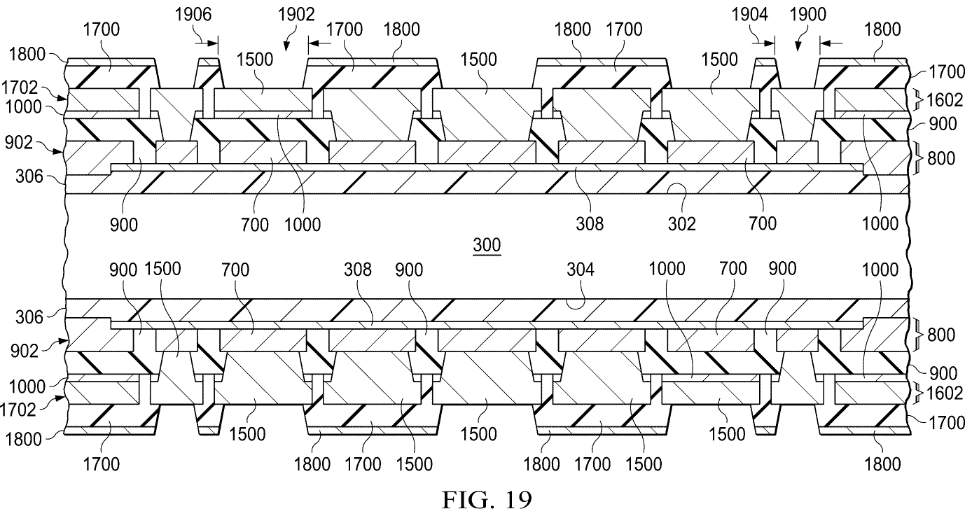

FIG. 21 illustrates an example of a nineteenth stage of the process flow. In the nineteenth stage, the passivation layer 2000 is patterned to have cured portions 2100 and uncured portions 2102. Accordingly, the passivation layer 2000 is a patterned passivation layer.

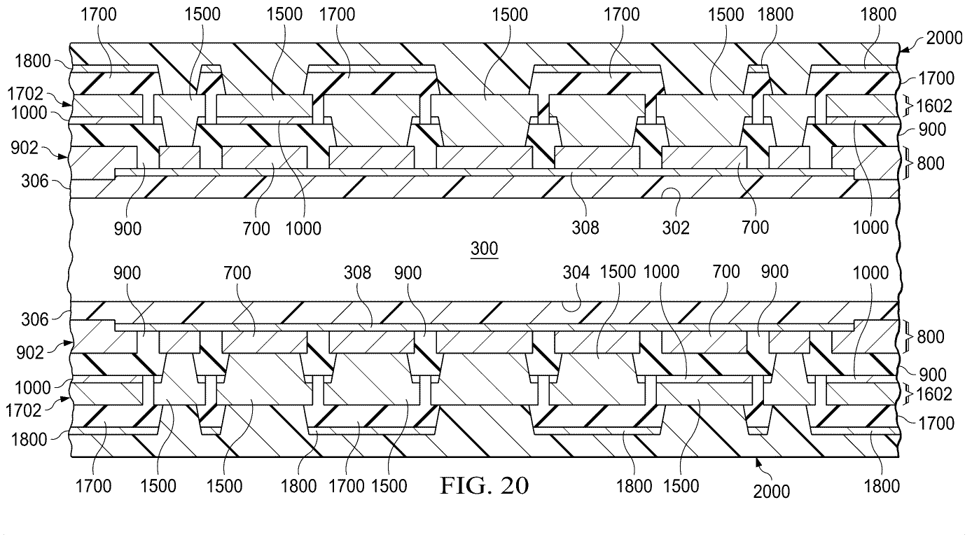

FIG. 22 illustrates an example of a twentieth stage of the process flow. In the twentieth stage, the uncured portions 2102 are removed from the seed layer 1800 leaving the cured portions 2100 and voids 2200 between the cured portions 2100. The voids 2200 exposing the seed layer 1800 and the openings, such as the second via opening 1900 and the third thermal bar opening 1902.

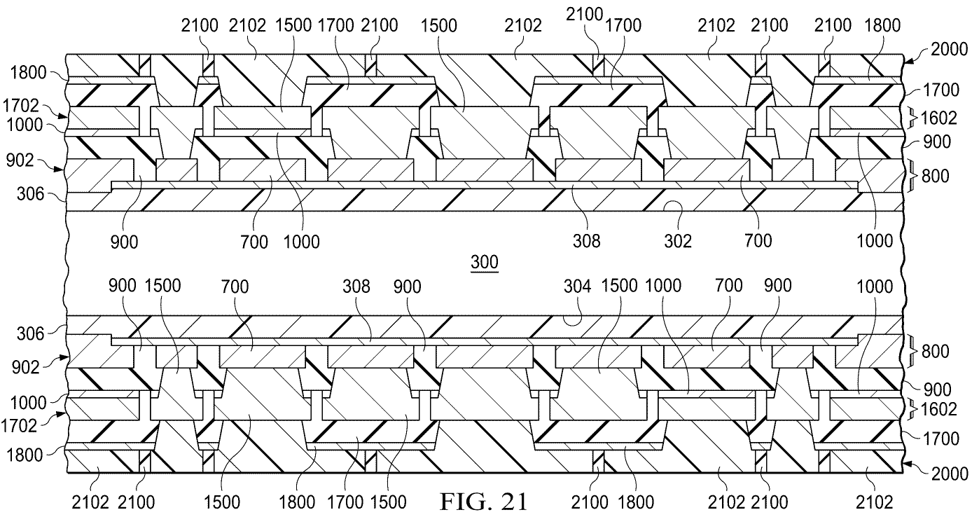

FIG. 23 illustrates an example of a twenty-first stage of the process flow. In the twenty-first stage, a conductive material 2300 is deposited over the voids 2200 exposing the seed layer 1800. For example, the conductive material 2300 in the third thermal bar opening 1902 forms a thermal bar. In some examples, the conductive material 2300 is the same conductive material used to form the first trace pattern 800 and/or the second trace pattern 1602.

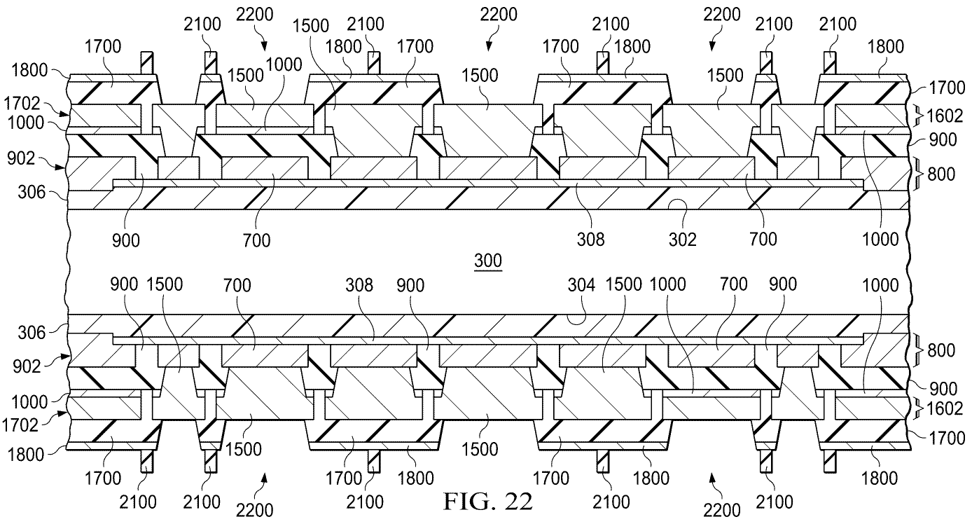

FIG. 24 illustrates an example of a twenty-second stage of the process flow. In the twenty-second stage, the cured portions 2100 are removed leaving voids 2400 and a third trace pattern 2402 of the conductive material. The third trace pattern forming a third metal trace layer (e.g., the third metal trace layer 146 of FIG. 1, the third metal trace layer 206 of FIG. 2).

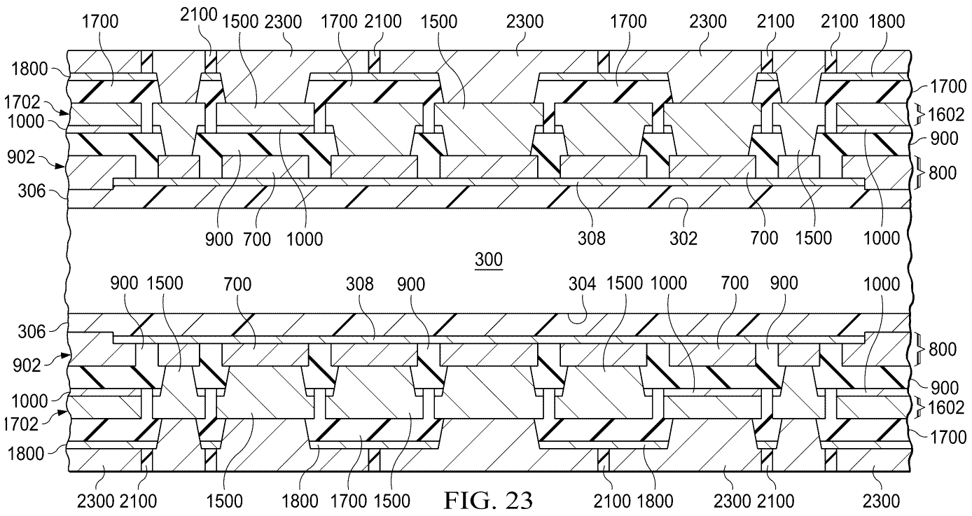

FIG. 25 illustrates an example of a twenty-third stage of the process flow. In the twenty-third stage, a protective layer 2500 is formed over the third trace pattern 2402. In some examples, the protective layer 2500 is a passivation layer (e.g., the passivation layer 400 of FIG. 4, the passivation layer 1200 of FIG. 12, the passivation layer 2000 of FIG. 20. For example, the protective layer 2500 may be formed of polysilicon, silicon nitride, silicon oxynitride, polyimide, etc.

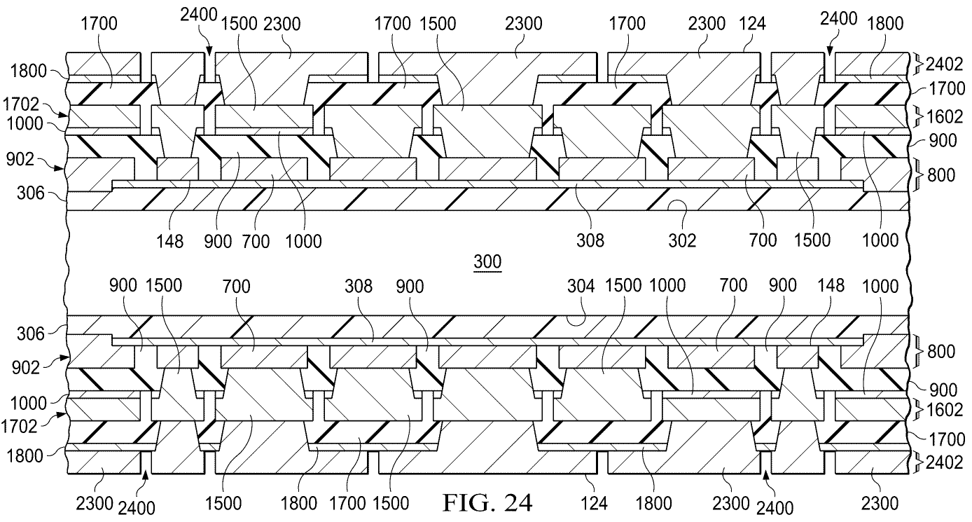

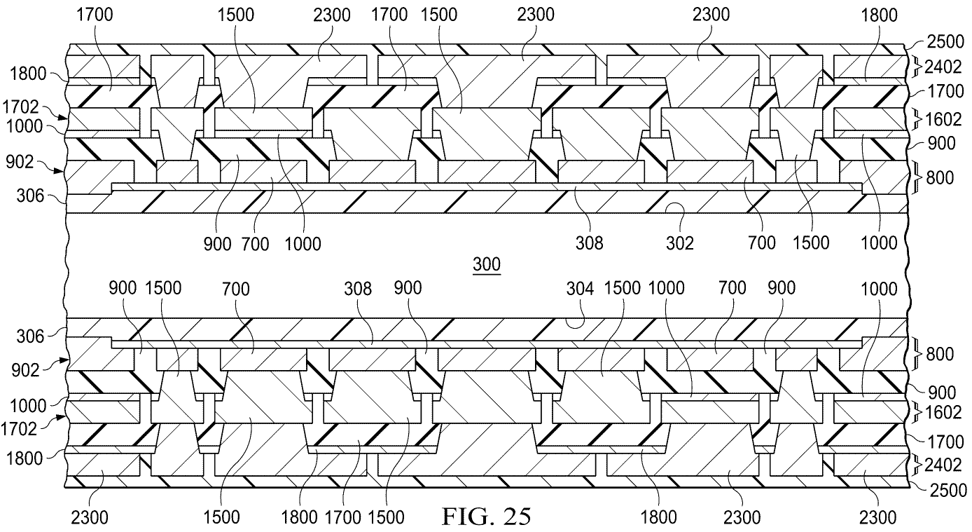

FIG. 26 illustrates an example of a twenty-fourth stage of the process flow. In the twenty-fourth stage, the package substrate is released from the carrier 300 at the separation film 306. For example, a first package substrate 2600 is released from the first carrier surface 302 of the carrier 300 and a second package substrate 2602 is released from the second carrier surface 304 of the carrier 300. Once the first package substrate 2600 is released from the carrier 300, the protective layer 2500 is removed from the first package substrate 2600, as shown in the twenty-fifth stage of FIG. 27. The protective layer 2500 may be removed using a developing agent. The package substrate 2600 extends from a first outer surface 2700 (e.g., a first outer surface 124 of FIG. 1) to a second outer surface 2702 (e.g., a second outer surface 148 of FIG. 1).

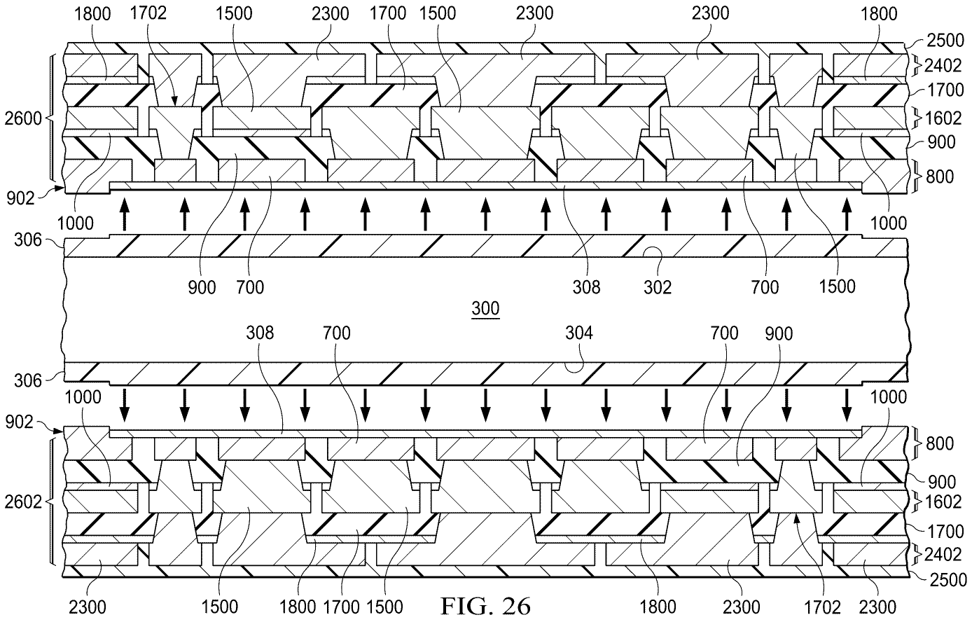

FIG. 28 illustrates an example of a twenty-sixth stage of the process flow. In the twenty-sixth stage, a first solder resist layer 2800 (e.g. the first solder resist layer 118 of FIG. 1) is applied to the first outer surface 2700 of the first package substrate 2600. A second solder resist layer 2802 (e.g., the second solder resist layer 120 of FIG. 1) is applied to the second outer surface 2702 of the first package substrate 2600. In some examples, the second solder resist layer 2802 is continuous in a lateral direction over the first thermal bar structure including thermal bars (e.g., the first thermal bar 132, the second thermal bar 144 of FIG. 1).

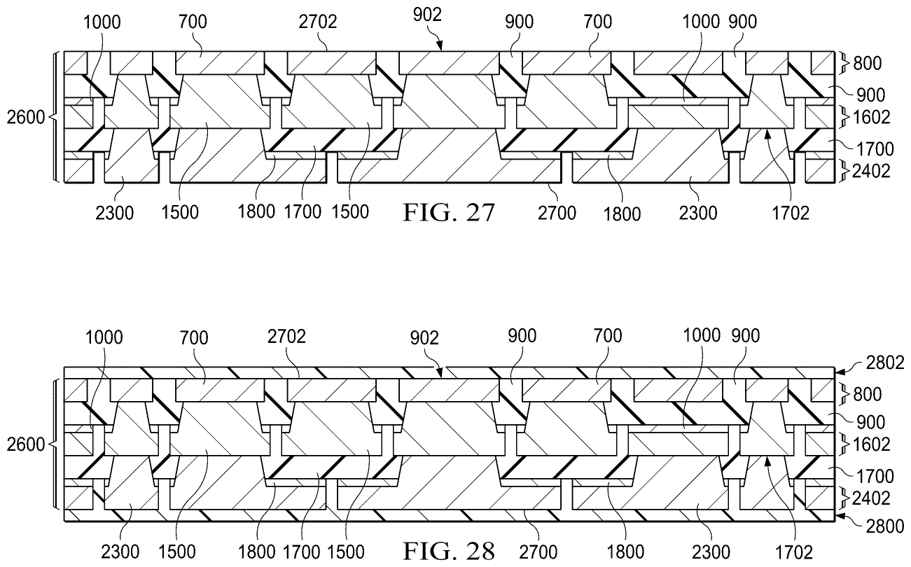

FIG. 29 illustrates an example of a twenty-seventh stage of the process flow. In the twenty-seventh stage, the first solder resist layer 2800 and the second solder resist layer 2802 are patterned to have cured portions 2900 and uncured portions 2902. For example, the first solder resist layer 2800 and the second solder resist layer 2802 passivation layer may be formed of a light-sensitive material used in several processes, including photolithography, photoengraving, and photoresist etching that allow underlying layers to be patterned. For example, a photomask may be transparent over the cured portions 2900 and be opaque over the uncured portions 2902 during radiation.

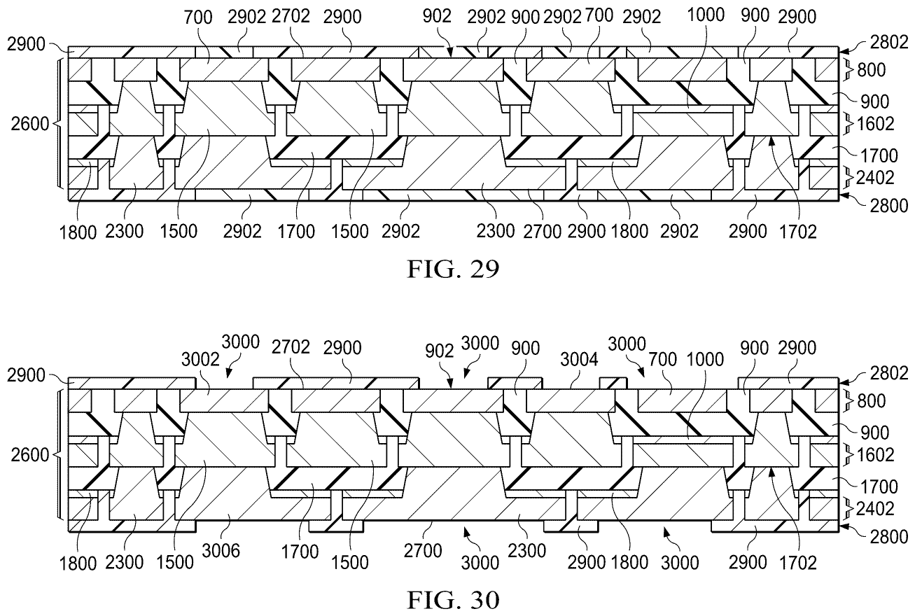

FIG. 30 illustrates an example of a twenty-eighth stage of the process flow. In the twenty-eighth stage, the uncured portions 2902 are removed from the from the first outer surface 2700 and the second outer surface 2702. The removal leaves voids 3000 between the cured portions 2900. The voids 3000 in the first solder resist layer 2800 exposes a first contact pad 3002 (e.g., the first contact pad 108 of FIG. 1) and a third contact pad 3004 (e.g., the third contact pad 116 of FIG. 1) at the first outer surface 2700. The voids 3000 in the second solder resist layer 2802 exposes a second contact pad 3006 (e.g., the second contact pad 112 of FIG. 1) at the second outer surface 2702. In some examples, the voids 3000 in the first solder resist layer 2800 may expose additional portions if the conductive material 2300 to form additional contact pads.

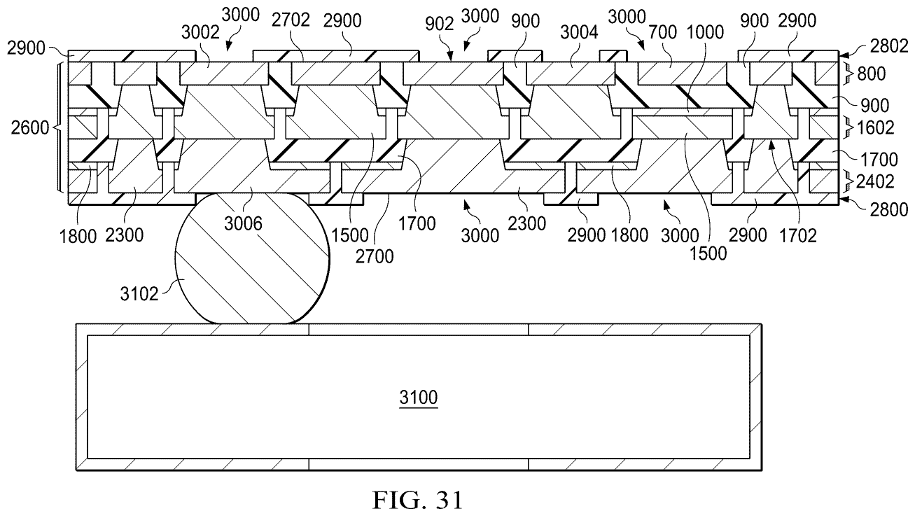

FIG. 31 illustrates an example of a twenty-ninth stage of the process flow. In the twenty-ninth stage, an electrical component 3100 (e.g., the electrical component 106 of FIG. 1) is affixed to a second contact pad 3006 at the second outer surface 2702 of the package substrate 2600. The electrical component 3100 is attached via an electrical contact 3102 (e.g. the electrical contact 114). The electrical contact 3102 may include a solder ball, a controlled collapse chip connection (C4) bump, a ball grid array (BGA), or a land grid array (LGA).

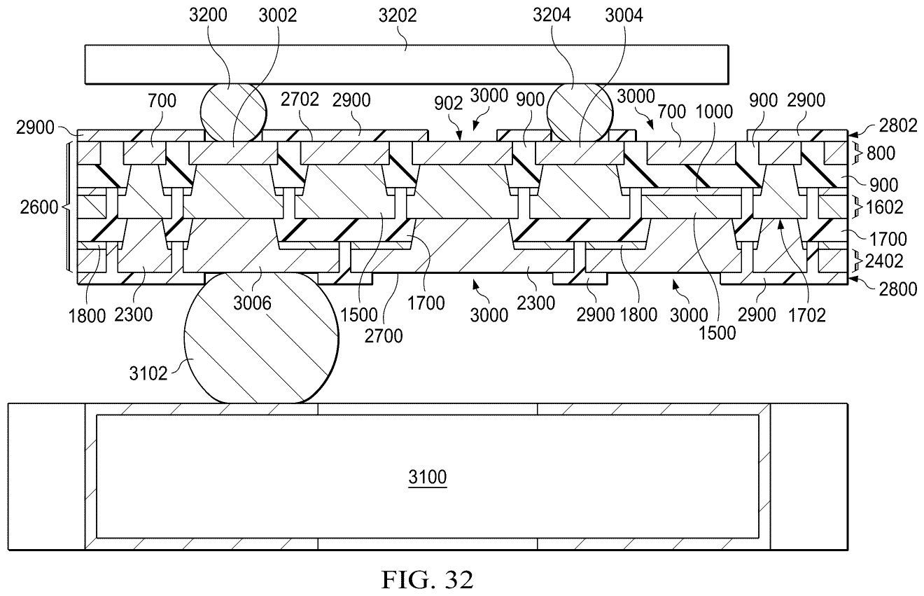

FIG. 32 illustrates an example of a thirtieth stage of the process flow. In the thirtieth stage, an inactive surface 3204 (e.g., the thermal pin 154 of FIG. 1) of the semiconductor die 3202 (e.g., the semiconductor die 104 of FIG. 1) is affixed to the package substrate 2600 at the third contact pad 3004. Thus, the inactive surface 3204 is a thermal pin for heat transfer. An electrical pathway is provided with a signal pin 3200 between the semiconductor die 3202 and the electrical component 3100 through the package substrate 2600 from the first contact pad 3002 to the second contact pad 3006. The third contact pad 3004 does not provide an electrical pathway between the semiconductor die 3202 and another electrical component 3100 (e.g., the electrical component 106 of FIG. 1). Instead, the third contact pad 3004 transfers heat generated by the semiconductor die 3202 away from the semiconductor die 3202. The thermal bars formed in the first thermal bar opening 1102, a second thermal bar opening 1108, and the third thermal bar opening 1902 draws heat from semiconductor devices affixed to the package substrate thereby improving thermal dissipation of the corresponding IC device. The larger surface area of the thermal bars, in comparison to the signal via, is proportional the heat dissipated from the semiconductor die 3202.

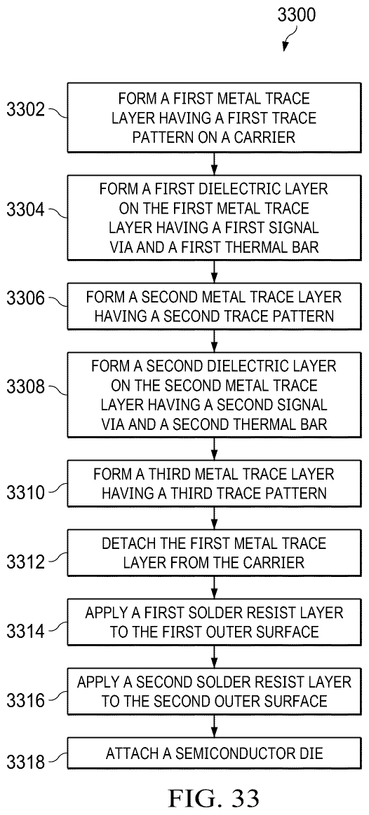

FIG. 33 illustrates a flowchart of an example method 3300 for fabricating semiconductor chip package.

At block 3302, the method 3300 includes forming a first metal trace layer (e.g., the first metal trace layer 122 of FIG. 1, the first metal trace layer 202 of FIG. 2, the first metal trace layer 902 of FIG. 9) having a first trace pattern (e.g., the first trace pattern 800) of a conductive material (e.g., the conductive material 700 of FIG. 7) on a first carrier surface (e.g., first carrier surface 302 of FIG. 3) a carrier (e.g., the carrier 300 of FIG. 3).

At block 3304, the method 3300 includes forming a first insulator layer (e.g., the first insulator layer 128 of FIG. 1) on the first metal trace layer, the first insulator layer including a first signal via (e.g., the first signal via 130 of FIG. 1) having a first via width (e.g., the via width 1104 of FIG. 11) and a first thermal bar (e.g., the first thermal bar 132 of FIG. 1) having a first thermal bar width (e.g., thermal bar width 1106 of FIG. 11). The first thermal bar width is at least twice the first via width in a lateral direction.

At block 3306, the method 3300 includes forming a second metal trace layer (e.g., the second metal trace layer 134 of FIG. 1, the second metal trace layer 204 of FIG. 2, the second metal trace layer 1702 of FIG. 17) including a second trace pattern (e.g., the second trace pattern 1602 of FIG. 16) of the conductive material (e.g., the conductive material 1500 of FIG. 15). The conductive material of the second trace pattern contacts the first signal via and the first thermal bar.

At block 3308, the method 3300 includes forming a second insulator layer (e.g., the second insulator layer 140 of FIG. 1) on the second metal trace layer. The second insulator layer including a second signal via (e.g., the second signal via 142 of FIG. 1) having a second via width (e.g., the via width 1104 of FIG. 11) and a second thermal bar (e.g., the second thermal bar 144 of FIG. 1) having a second thermal bar width (e.g., the thermal bar width 1106 of FIG. 11). The second thermal bar width is at least twice the second via width.

At block 3310, the method 3300 includes forming a third metal trace layer (e.g., the third metal trace layer 146 of FIG. 1, the third metal trace layer 206 of FIG. 2) including a third trace pattern (e.g., a third trace pattern 2402 of FIG. 24) of the conductive material (e.g., the conductive material 2300 of FIG. 23). The conductive material of the third trace pattern contacts the second signal via and the second thermal bar.

At block 3312, the method 3300 includes detaching the first metal trace layer from the carrier. The package substrate extends from a first outer surface (e.g., a first outer surface 124 of FIG. 1, the first outer surface 2700 of FIG. 27) of the first metal trace layer to a second outer surface (e.g., a second outer surface 148 of FIG. 1, the second outer surface 2702 of FIG. 27) at the third metal trace layer.

At block 3314, the method 3300 includes applying a first solder resist layer (e.g., the first solder resist layer 118 of FIG. 1, the first solder resist layer 2800 of FIG. 28) to the first outer surface (e.g., the first outer surface 124 of FIG. 1, the first outer surface 2700 of FIG. 27). The first solder resist layer exposes a first contact pad (e.g., the first contact pad 108 of FIG. 1, the first contact pad 3002 of FIG. 30) at the first outer surface.

At block 3316, the method 3300 includes applying a second solder resist layer (e.g., the second solder resist layer 120 of FIG. 1, the first solder resist layer 2802 of FIG. 28) to the second outer surface (e.g., the first outer surface 124 of FIG. 1, the first outer surface 2700 of FIG. 27). The second solder resist layer exposes a second contact pad (e.g., the second contact pad 112 of FIG. 1, the second contact pad 3006 of FIG. 30) separated from the first contact pad by the first signal via and the second signal via in a longitudinal direction.

At block 3318, the method 3300 includes affixing a semiconductor die (e.g., the semiconductor die 104 of FIG. 1, the semiconductor die 3202 of FIG. 32) to the package substrate (e.g., the package substrate 102 of FIG. 1, the package substrate 2600 of FIG. 26) at the second contact pad. An electrical pathway is provided between the semiconductor die and an electrical component (e.g., the electrical component 106 of FIG. 1, the electrical component 3100 of FIG. 31) through the package substrate from the first contact pad to the second contact pad.

The semiconductor die 3202 is also attached at the package substrate at an inactive surface (e.g., the thermal pin 154 of FIG. 1, the inactive surface 3200 of FIG. 32) of the semiconductor die is affixed to the package substrate at the third contact pad (e.g., the third contact pad 116 of FIG. 1, the third contact pad 3004 of FIG. 30). The thermal pin is an inactive surface of the semiconductor die. Accordingly, the third contact pad does not provide an electrical pathway between the semiconductor die and another electrical component, such as the electrical component. Instead, heat is transferred away from semiconductor die 3202.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications, and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

In this description, unless otherwise stated, “about,” “approximately” or “substantially” preceding a parameter means being within +/−10 percent of that parameter. Modifications are possible in the described embodiments, and other embodiments are possible, within the scope of the claims.

Further, unless specified otherwise, “first”, “second”, or the like are not intended to imply a temporal aspect, a spatial aspect, an ordering, etc. Rather, such terms are merely used as identifiers, names, etc. for features, elements, items, etc. For example, a first channel and a second channel generally correspond to channel A and channel B or two different or two identical channels or the same channel. Additionally, “comprising”, “comprises”, “including”, “includes”, or the like generally means comprising or including, but not limited to.

It will be appreciated that several of the above-disclosed and other features and functions, or alternatives or varieties thereof, may be desirably combined into many other different systems or applications. Also, that various presently unforeseen or unanticipated alternatives, modifications, variations or improvements therein may be subsequently made by those skilled in the art which are also intended to be encompassed by the following claims.

What is claimed is:

1. A method of forming a package substrate for an integrated circuit (IC) device, comprising:
forming a first metal trace layer having a first trace pattern of a conductive material on a first carrier surface of a carrier;
forming a first insulator layer on the first metal trace layer, the first insulator layer including a first signal via having a first via width and a first thermal bar having a first thermal bar width, wherein the first thermal bar width is at least twice the first via width in a lateral direction;
forming a second metal trace layer including a second trace pattern of the conductive material, wherein the conductive material of the second trace pattern contacts the first signal via and the first thermal bar;
forming a second insulator layer on the second metal trace layer, the second insulator layer including a second signal via having a second via width and a second thermal bar having a second thermal bar width, wherein the second thermal bar width is at least twice the second via width;
forming a third metal trace layer including a third trace pattern of the conductive material, wherein the conductive material of the third trace pattern contacts the second signal via and the second thermal bar; and
detaching the first metal trace layer from the carrier, wherein the package substrate extends from a first outer surface of the first metal trace layer to a second outer surface at the third metal trace layer.

2. The method of claim 1, further comprising:
applying a first solder resist layer to the first outer surface, wherein the first solder resist layer exposes a first contact pad at the first outer surface; and
applying a second solder resist layer to the second outer surface, the second solder resist layer exposes a second contact pad separated from the first contact pad by the first signal via and the second signal via in a longitudinal direction.

3. The method of claim 2, further comprising:
affixing a semiconductor die at the second contact pad.

4. The method of claim 2, wherein the first solder resist layer or the second solder resist layer is continuous in a lateral direction over the first thermal bar.

5. The method of claim 1, wherein forming the first metal trace layer comprises:
applying a first patterned passivation layer on the first carrier surface of the carrier, and
applying the conductive material to the first patterned passivation layer.

6. The method of claim 1, wherein forming the first insulator layer comprises:
depositing a insulator material on the first metal trace layer;
drilling a single via opening to form a first via opening in the insulator material and a series of overlapping via openings to form the first thermal bar opening in the insulator material, wherein the first thermal bar opening is separated from the single via opening in a lateral direction; and
depositing the conductive material in the first via opening to form the first signal via and the first thermal bar.

7. The method of claim 1, wherein the drilling is performed with a laser drill.

8. The method of claim 1, wherein forming the second insulator layer comprises:
depositing a insulator material on the second metal trace layer;
drilling a single via opening to form a second via opening in the insulator material and a series of overlapping via openings to form the second thermal bar opening in the insulator material, wherein the second thermal bar opening is separated from the single via opening in a lateral direction; and
depositing the conductive material in the second via opening to form the second signal via and the second thermal bar.

9. The method of claim 8, wherein the conductive material is copper and the insulator material is a prepeg material.

10. The method of claim 1, wherein the package substrate is a first package substrate, and wherein a second package substrate is formed on a second carrier surface of the carrier.

11. A method of forming an integrated circuit (IC) device, comprising:
forming a first metal trace layer of a conductive material on a first carrier surface of a carrier;
depositing a insulator material on the first metal trace layer;
drilling a first single via opening to form a first via opening in the insulator material and a first series of overlapping via openings to form a first thermal bar opening in the insulator material, wherein the first thermal bar opening is separated from the single via opening in a lateral direction; and
depositing the conductive material in the first via opening to form a first signal via and the first thermal bar;
forming a second metal trace layer including a second trace pattern of the conductive material, wherein the conductive material of the second trace pattern contacts the first signal via and the first thermal bar;
depositing the insulator material on the second metal trace layer;
drilling a second single via opening to form a second via opening in the insulator material and a second series of overlapping via openings to form a second thermal bar opening in the insulator material, wherein the second thermal bar opening is separated from the single via opening in a lateral direction;
depositing the conductive material in the second via opening to form a second signal via and the second thermal bar;
forming a third metal trace layer including a third trace pattern of the conductive material, wherein the conductive material of the third trace pattern contacts the second signal via and the second thermal bar;
detaching the first metal trace layer from the carrier forming a package substrate that extends from a first outer surface of the first metal trace layer to a second outer surface at the third metal trace layer;
applying a first solder resist layer to the first outer surface, wherein the first solder resist layer has a first mounting opening in the first outer surface;
applying a second solder resist layer to the second outer surface, the second solder resist layer having a second mounting opening separated from the first mounting opening by the first signal via and the second signal via in a longitudinal direction; and
attaching a semiconductor die at a second contact pad at the second mounting opening.

12. The method of claim 11, wherein the first solder resist layer or the second solder resist layer is continuous in the lateral direction over the first thermal bar.

13. The method of claim 11, wherein the conductive material is copper and the insulator material is a prepeg material.

14. The method of claim 11, wherein the second solder resist layer has a third mounting opening positioned over the first thermal bar and the second thermal bar, and wherein an inactive surface of the semiconductor die is affixed to the third metal trace layer at the third mounting opening.

15. The method of claim 14, wherein the inactive surface is a thermal pin for heat transfer.

16. An integrated circuit (IC) device comprising:
a first metal trace layer having a first trace pattern of a conductive material;
a first insulator layer over the first metal trace layer, the first insulator layer having a insulator material including a first signal via of the conductive material having a first via width and a first thermal bar of the conductive material having a first thermal bar width;
a second metal trace layer including a second trace pattern of the conductive material, wherein the conductive material of the second trace pattern contacts the first signal via and the first thermal bar;
a second insulator layer on the second metal trace layer, the second insulator layer of the insulator material including a second signal via of the conductive material having a second via width and a second thermal bar of the conductive material having a second thermal bar width; and
a third metal trace layer including a third trace pattern of the conductive material, the conductive material of the third trace pattern contacts the second signal via and the second thermal bar.

17. The IC device of claim 16, further comprising:
a first solder resist layer to a first outer surface of the first metal trace layer, wherein the first solder resist layer exposes a first contact pad at the first outer surface; and
a second solder resist layer to a second outer surface of the third metal trace layer, the second solder resist layer exposes a second contact pad separated from the first contact pad by the first signal via and the second signal via in a longitudinal direction.

18. The IC device of claim 17, further comprising:
a device affixed at the first contact pad.

19. The IC device of claim 16, wherein the first thermal bar width is at least twice the first via width in a lateral direction.

20. The IC device of claim 16, wherein the conductive material is copper and the insulator material is a prepeg material.
